(19) United States
(12) Patent Application Publication
(10) Pub. No.: US 2010/0159699 A1
(43) Pub. Date: Jun. 24, 2010

(54) SANDBLAST ETCHING FOR THROUGH SEMICONDUCTOR VIAS

(76) Inventor: Yoshimi Takahashi, Beppu-city (JP)

Correspondence Address: TEXAS INSTRUMENTS INCORPORATED, P O BOX 655474, M/S 3999, DALLAS, TX, 75265, US

(21) Appl. No.: 12/640,995

(22) Filed: Dec. 17, 2009

Related U.S. Application Data
(60) Provisional application No. 61/139,417, filed on Dec. 19, 2008.

(51) Int. Cl. H01L 21/304; B24C 1/00

(52) U.S. Cl. 438/693; 451/38; 257/E21.239

(57) ABSTRACT

To provide selective exposure of the TSV tip through a semiconductor wafer without undercut, the inventor has developed a new method of semiconductor device formation. An embodiment of the present teachings can include the use of sandblasting to remove a portion of the semiconductor wafer to expose the TSV tip without the need for additional wet and/or dry etching.

### PRIORITY CLAIM

This application claims priority to U.S. Provisional Application Ser. No. 61/139,417, filed Dec. 19, 2008, which is hereby incorporated in its entirety by reference.

### FIELD OF THE INVENTION

This invention relates to the field of semiconductor device manufacture, and more particularly to a method for exposing the tips of through semiconductor vias (TSV).

### BACKGROUND OF THE INVENTION

This section introduces aspects that may be helpful in facilitating a better understanding of the invention. Accordingly, the statements of this section are to be read in this light and are not to be understood as admissions about what is in the prior art or what is not in the prior art.

Semiconductor devices typically include a semiconductor wafer section such as a semiconductor die having a circuit (i.e. front) side with circuitry thereon, and a noncircuit (i.e. back) side. To protect the semiconductor die, the back and/or front surface can be encapsulated in a plastic resin material or protected by a thin passivation layer.

A semiconductor device can further include one or more conductor-filled openings which extend from the circuit side to the noncircuit side of the semiconductor die, referred to as through-substrate vias (TSV's) or through-semiconductor vias. TSV's are vertical electrical connections that extend from one of the electrically conductive levels formed on the top surface of a wafer or IC die (e.g., contact level or one of the metal interconnect levels) to the backside (bottom) surface. As a result, a TSV device can be bonded face-up and utilize vertical electrical paths to couple to other IC devices (e.g., on a die, wafer, etc.) or to mount to a receiving substrate. The vertical electrical paths can be significantly shortened relative to conventional wire bonding technology, generally leading to significantly faster device operation.

To fabricate a TSV, openings are formed to a depth less than the full wafer thickness using chemical etching, laser drilling, or one of several energetic etching methods, such as reactive ion etching (RIE), also known as plasma etching. Once the vias are formed, a dielectric liner is formed in the openings to provide electrical isolation from the surrounding substrate then the openings are filled with a conductor (e.g., copper, tungsten, or doped polysilicon) to form embedded TSV's. The bottom of the embedded TSV is generally referred to as an embedded TSV tip. Since most electrically conductive filler materials are metals that can degrade minority carrier lifetimes (e.g., copper or tungsten), a barrier layer is generally deposited on the dielectric liner. In the case of an electroplated metal (e.g., copper) process, a seed layer is generally added after the barrier layer. The barrier layer can be, for example, Ta.

A back grinding step then thins the wafer by removing a sufficient thickness of the substrate from the bottom surface of the wafer to reach the embedded TSV tip to expose the electrically conductive filler material at the distal end of the TSV tip. The high substrate removal rate provided by the back grinding process is needed for manufacturability due to the large substrate thickness being removed. A subsequent polish step (wet or dry) can be used to remove a thickness of material from the bottom surface of the substrate in an attempt to reduce the mechanical damage and contamination generated by the back grinding process. Alternatively or additionally, a wet or dry chemical etch can also be used to reduce the mechanical damage and the contamination resulting from the back grinding.

The distal end of the completed TSV tip is conventionally flush with the bottom surface of the substrate. Alternatively, the semiconductor surrounding at least the TSV tip can be exposed through etching (wet or dry). However, conventional etching processes typically over etch the semiconductor around the TSV tip resulting in a void area. A solder bump or other electrically conductive finish may be added to the TSV tip prior to assembly to a workpiece which protrudes outward a relatively short distance from bottom surface of the substrate.

Once completed TSV's can be used to transfer a signal from the circuit side of the die to the back side, for example to provide back-side access to a ground node on the front of the die. TSV's can also be used to transfer a signal through the die from another device or a receiving substrate upon which the die is mounted. Once attached to another device or receiving substrate, an encapsulation material can be formed over the TSV die. One process, referred to as “glob top,” covers the die in a liquid adhesive and then cures the adhesive. Another process forms a molded encapsulation by injecting a liquid mold compound under pressure into a frame in contact with the receiving substrate.

### SUMMARY OF THE EMBODIMENTS

The inventor has realized that manufacturing a semiconductor device using multiple polishing and/or etching steps to expose the TSV tip can be wasteful and time consuming. For example, using multiple grinding, polishing, and/or etching steps (e.g., wet and/or dry chemical etches) to selectively expose the TSV tip can require multiple machines and reduce throughput time. Also, if one or more of the chemical etchants used does not have sufficient selectivity, then undercutting around the TSV tip can occur.

To provide selective exposure of the TSV tip through a semiconductor wafer without undercut, the inventor has developed a new method of semiconductor device formation. An embodiment of the present teachings can include the use of sandblasting to remove a portion of the semiconductor wafer to expose the TSV tip without the need for additional wet and/or dry etching.

A sandblasting system can be configured to replace the conventional etching machines and polishers used to back grind the semiconductor wafer and to perform the additional polishing steps used to expose the embedded TSV tip. For example, a sandblasting system can be configured to use a stream of compressed air mixed with pressurized sand to sandblast the back surface of the semiconductor wafer. An air stream can be compressed and injected into a pressurized tank including sand, which can then force a mix of the air and sand through a projection nozzle onto the back surface of the semiconductor wafer. The projection nozzle can be configured to move along the back surface of the semiconductor wafer in any pattern required to selectively remove semiconductor while leaving the copper TSV tip intact.

A pressurized mixture of air and sand has been found to selectively expose the embed TSV tip without significant damage or undercutting, while removing the semiconductor at a sufficient rate. The inventor has determined that sandblasting removes hard material (e.g., silicon and Ta) at a considerably faster rate than soft material (e.g., Cu), which can be advantageously applied to the problem discussed above. The selectivity of the sandblasting mixture depends on the composition of the sand, the grain size, etc., and the sandblasting processing conditions, e.g., temperature, blow pressure, etc.

Because sandblasting has a high selectivity and is a comparatively fast etching process, the semiconductor wafer (e.g., Si) and buffer layers (e.g., Ta) can be removed while exposing the TSV tip without undercutting or significant damage to the TSV tip.

### BRIEF DESCRIPTION OF THE DRAWINGS

Some embodiments of methods in accordance with embodiments of the present invention are now described, by way of example only, and with reference to the accompanying drawings, in which:

FIGS. 1A-1C show conventional examples of a TSV tip exposed during dry and wet etch;

FIGS. 2A-2C show cross sections of a method of sandblasting according to present teachings;

FIG. 3 is a flow chart of the method of sandblasting shown in FIGS. 2A-2C; and

FIG. 4 shows a sandblasting apparatus according to present teachings.

### DETAILED DESCRIPTION

Reference will now be made in detail to the present embodiments (exemplary embodiments) of the invention, examples of which are illustrated in the accompanying drawings. Wherever possible, the same reference numbers will be used throughout the drawings to refer to the same or like parts. In the following description, reference is made to the accompanying drawings that form a part thereof, and in which is shown by way of illustration specific exemplary embodiments in which the invention may be practiced. These embodiments are described in sufficient detail to enable those skilled in the art to practice the invention and it is to be understood that other embodiments may be utilized and that changes may be made without departing from the scope of the invention. The following description is, therefore, merely exemplary.

For simplicity and illustrative purposes, the principles of the present invention are described by referring mainly to exemplary embodiments thereof. However, one of ordinary skill in the art would readily recognize that the same principles are equally applicable to, and can be implemented in, all types of secure distributed environments and that any such variations do not depart from the true spirit and scope of the present invention. Moreover, in the following detailed description, references are made to the accompanying figures, which illustrate specific embodiments. Electrical, mechanical, logical and structural changes can be made to the embodiments without departing from the spirit and scope of the present invention. The following detailed description is, therefore, not to be taken in a limiting sense and the scope of the present invention is defined by the appended claims and their equivalents.

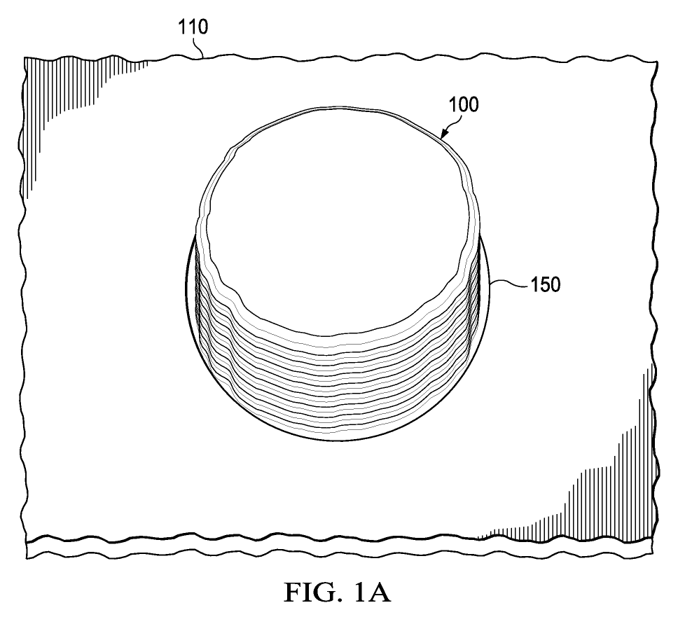

Embodiments according to present teachings include methods of and apparatuses for sandblasting semiconductor substrates to expose TSVs. As discussed above, conventional processes can use backside grinding of semiconductor substrates that can be used to expose TSVs and can include wet and/or dry etches. However, as shown in FIGS. 1A-1C, these types of etches can result in over etching 150 of the TSV tip 100 of TSV 130, and barrier layer 120 buried in a semiconductor substrate 110. FIG. 1A is an example of the results of a dry etch and FIG. 1B is an example of a wet etch.

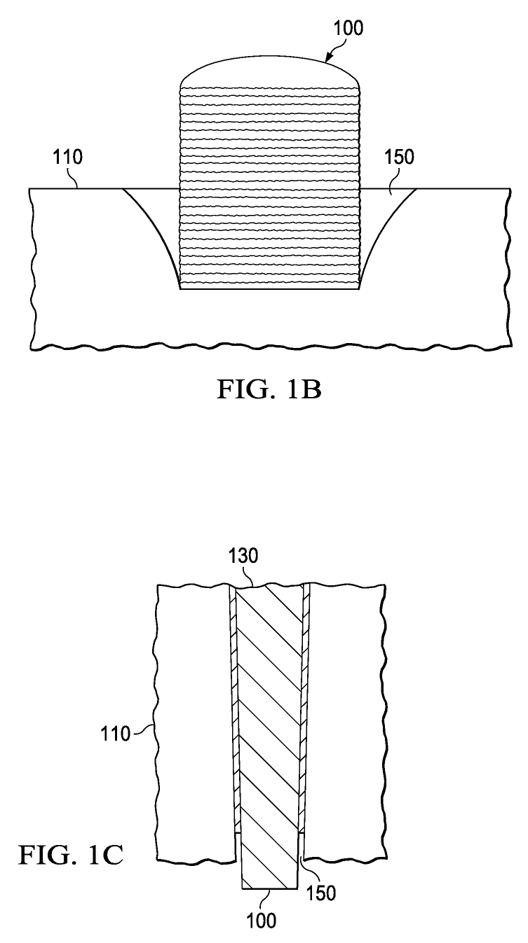

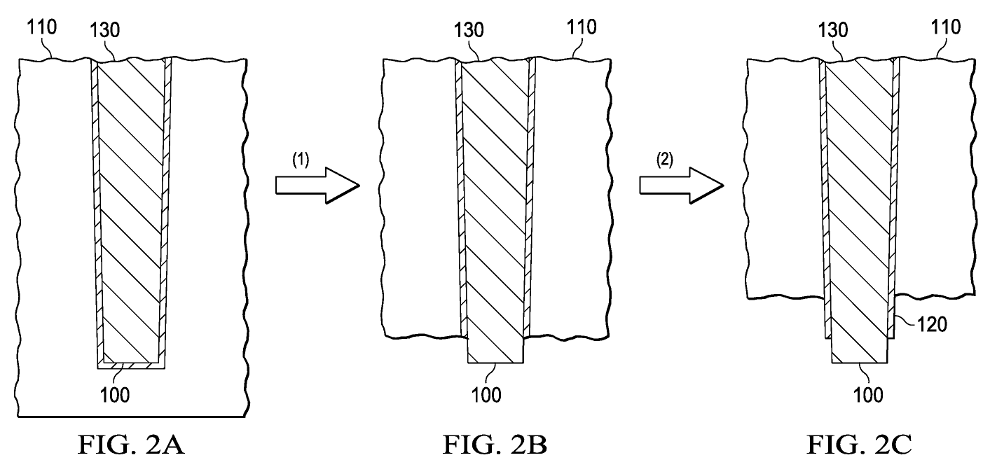

FIGS. 2A-2C and FIG. 3 illustrate an embodiment according to present teachings of a method of exposing the tip 100 of TSV 130. In FIG. 2A and according to step 300, a semiconductor substrate 110 including TSVs 130 is provided. Backside grinding can optionally be used to remove a portion of the semiconductor wafer 110 prior to the sandblasting process of step 310. In step 310 and as shown in FIG. 2B, selective removing of the semiconductor substrate 110 can be done through sandblasting. The sandblasting can selectively expose the TSV tip 100 through the semiconductor substrate 110 without significant undercut and/or significant damage to the TSV tip 100, as shown in FIG. 2C and step 320 of FIG. 3. For purposes of this discussion, the tip 100 of a TSV 130 is intended to include at least a portion of the surface of the end of the TSV 130 embedded closest to the backside of the semiconductor wafer 110.

The semiconductor substrate 110 can be any known type, for example, silicon. The TSV can be, for example, Cu with a barrier layer surrounding the TSV of, for example, Ta. As one of skill in the art will appreciate, an oxide layer (not shown) can be formed between the barrier layer 120 and the semiconductor substrate 110, e.g., silicon dioxide, which can also be selectively removed with the semiconductor substrate and the barrier layer.

Sandblasting can be advantageously used to selectively remove the semiconductor substrate 110 because the sandblasting can remove harder materials faster than softer materials. For example, harder materials can have a hardness equal to or greater than about 1 GPa (e.g., mono-crystalline silicon has a hardness of about 8.3 GPa, SiO₂ has a hardness of about 4 to about 6 GPa, and Ta (e.g., TaN) has a hardness of about 6 GPa. In contrast, softer materials, e.g., Cu, has a hardness of about 0.4 GPa. The selectivity of the sandblasting composition can depend on the composition of the sand (e.g., glass), the grain size, etc., and the sandblasting processing conditions, e.g., temperature (e.g., less than 100° C.), blow pressure, etc.

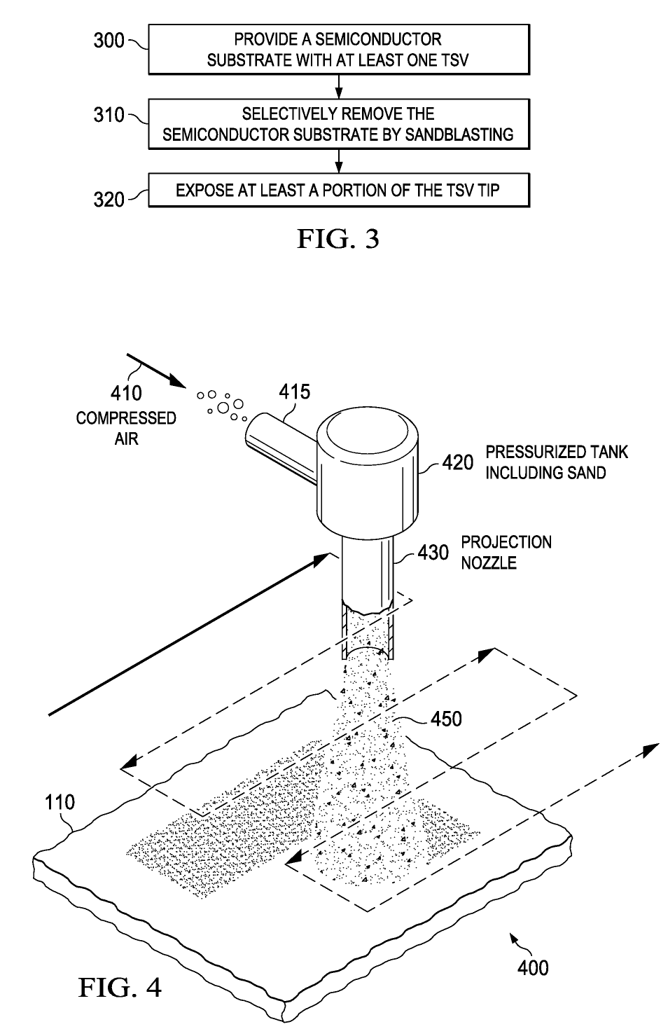

An embodiment of a sandblasting system 400 according to present teachings is shown in FIG. 4. Sandblasting system 400 can be configured to replace conventional etching machines used to expose the embedded TSV tip 100. For example, sandblasting system 400 can include a pressurized sand tank 420 holding sand into which compressed air 410 can be injected and mixed through an inlet 415. The pressurized mixed air and sand 540 can then be forced through a projection nozzle 430. The projected mixture 450 can selectively remove the semiconductor substrate to expose the TSV tip 100 (not shown) and a portion of the TSV 100 (not shown). The sandblasting system 400, including the projection nozzle 430 can be configured to move along the back surface of the semiconductor substrate 110 in any pattern required to selectively remove semiconductor substrate 110 while leaving the TSV tip 100 (not shown) intact. Sandblasting system 400 can be configured to move in three dimensions, e.g., vertically, horizontally, and depth, and/or the semiconductor substrate 110 can be moved in three dimensions to allow for precise control of the projected sandblasting mixture 450.

While the present teachings have been illustrated with respect to one or more implementations, alterations and/or modifications can be made to the illustrated examples without departing from the spirit and scope of the appended claims. In addition, while a particular feature of the present teachings may have been disclosed with respect to only one of several implementations, such feature may be combined with one or more other features of the other implementations as may be desired and advantageous for any given or particular function. Furthermore, to the extent that the terms “including”, “includes”, “having”, “has”, “with”, or variants thereof are used in either the detailed description and the claims, such terms are intended to be inclusive in a manner similar to the term “comprising.” As used herein, the term “one or more of” with respect to a listing of items such as, for example, A and B, means A alone, B alone, or A and B. The term “at least one of” is used to mean one or more of the listed items can be selected.

Notwithstanding that the numerical ranges and parameters setting forth the broad scope of the present teachings are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5. In certain cases, the numerical values as stated for the parameter can take on negative values. In this case, the example value of range stated as “less than 10” can assume values as defined earlier plus negative values, e.g. −1, −1.2, −1.89, −2, −2.5, −3, −10, −20, −30, etc.

1. A method of exposing a through semiconductor via (TSV) embedded in a silicon wafer, comprising:
mixing a compressed gas with sand;
projecting the mixture through a pressurized nozzle towards a back surface of the silicon wafer;
selectively removing a portion of the back surface of the silicon wafer by the projected mixture to expose at least a portion of the embedded TSV.

2. The method of claim 1, wherein the mixing further comprises:
injecting compressed air into a pressurized tank filled with at least a portion of sand;

3. The method of claim 1, wherein projecting further comprises:
projecting the mixture at a temperature of about 100° C.

4. The method of claim 1, wherein the TSV comprises copper and wherein selectively removing further comprises, removing silicon faster than copper.

5. The method of claim 1, wherein selectively removing further comprises:
removing a metal barrier layer surrounding the TSV; and
removing an oxide layer between the barrier layer and the silicon wafer.

6. A method for exposing through semiconductor vias (TSVs) of a semiconductor device, comprising:
providing a silicon wafer substrate comprising at least one TSV embedded therein;
selectively removing a portion of the back surface of the silicon wafer by sandblasting; and
exposing at least a portion of the at least one TSV during the sandblasting.

7. The method of claim 6, wherein selectively removing further comprises:
removing a metal barrier layer surrounding the TSV; and
removing an oxide layer between the barrier layer and the silicon wafer.

8. The method of claim 6, wherein selectively removing further comprises:
sandblasting at a temperature of less than about 100° C.

9. The method of claim 6, wherein selectively removing further comprises:
sandblasting with a mixture of ionized air and glass.

10. The method of claim 6, further comprising:
repeating the method for a plurality of TSVs embedded in the silicon wafer.
